(19) United States
(12) Patent Application Publication
(10) Pub. No.: US 2015/0345019 A1
(43) Pub. Date: Dec. 3, 2015

(54) METHOD AND APPARATUS FOR IMPROVING GAS FLOW IN A SUBSTRATE PROCESSING CHAMBER

(71) Applicant: Applied Materials, Inc., Santa Clara, CA (US)

(72) Inventors: XIAOXIONG YUAN, San Jose, CA (US); KARTIK SHAH, Sunnyvale, CA (US); DHRITIMAN SUBHA KASHYAP, Bangalore (IN); UMESH M. KELKAR, Santa Clara, CA (US); DIEN-YEH WU, San Jose, CA (US); MUHAMMAD M. RASHEED, San Jose, CA (US)

(73) Assignee: Applied Materials, Inc., Santa Clara, CA (US)

(21) Appl. No.: 14/291,807

(22) Filed: May 30, 2014

(51) Int. Cl. C23C 16/455; C23C 16/458; C23C 16/08

(52) U.S. Cl. CPC C23C 16/45544; C23C 16/08; C23C 16/458

(57) ABSTRACT

Embodiments of methods and apparatus for improving gas flow in a substrate processing chamber are provided herein. In some embodiments, a substrate processing chamber includes: a chamber body and a chamber lid defining an interior volume; a substrate support disposed within the interior volume and having a support surface to support a substrate; a gas passageway disposed in the lid opposite the substrate support to supply a gas mixture to the interior volume, the gas passageway including a first portion and a second portion; a first gas inlet disposed in the first portion to supply a first gas to the first portion of the gas passageway; and a second gas inlet disposed in the second portion to supply a second gas to the second portion.

### FIELD

Embodiments of the present disclosure generally relate to methods and apparatus for processing a substrate.

### BACKGROUND

Some deposition processes result in highly non-uniform deposition. For example, in some existing atomic layer deposition (ALD) chambers, one or more inlets mounted at different locations above a diverging funnel supply various gases to an interior of the chamber. The gases then swirl around inside of the funnel and mix together. However, although the mixing of gases is beneficial for many applications, under some conditions, the inventors have observed that the mixing may be non-uniform and centrifugal forces of the swirling flow may drive a precursor away from a center of the substrate. As a result, deposition is undesirably low at the center and the edge of the substrate.

Therefore, the inventors have provided embodiments of improved methods and apparatus for processing a substrate.

### SUMMARY

Embodiments of methods and apparatus for improving gas flow in a substrate processing chamber are provided herein. In some embodiments, a substrate processing chamber includes a chamber body and a chamber lid defining an interior volume; a substrate support disposed within the interior volume and having a support surface to support a substrate; a gas passageway disposed in the lid opposite the substrate support to supply a gas mixture to the interior volume, the gas passageway including a first portion and a second portion, wherein the first portion has an inner sidewall disposed at a first angle with respect to the support surface of the substrate support, and wherein the second portion has an inner sidewall disposed at a second angle with respect to the support surface, the second angle less than the first angle; a first gas inlet disposed in the first portion to supply a first gas to the first portion of the gas passageway; and a second gas inlet disposed in the second portion to supply a second gas to the second portion.

In some embodiments, a substrate processing chamber includes an interior volume; a substrate support disposed within the interior volume; a gas passageway disposed above the substrate support to supply a gas mixture to the interior volume, the gas passageway including a straight portion and a divergent portion; a plurality of first gas inlets to supply at least one gas to the straight portion at a first flow rate; and a second gas inlet to supply a second gas to the divergent portion at a second flow rate.

In some embodiments, a method of processing a substrate in a process chamber includes: supplying a first gas to a first portion of a gas passageway disposed above a substrate support via a first gas inlet at a first flow rate; supplying a second gas to a second portion of the gas passageway via a second gas inlet at a second flow rate, wherein the second portion of the gas passageway is closer to the substrate support than the first portion; mixing the first and second gases in the second portion to create a gas mixture; and supplying the gas mixture to an inner volume of the process chamber.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a substrate processing apparatus in accordance with some embodiments of the present disclosure.

FIG. 2 depicts a view of the gas passageway of the substrate processing chamber of FIG. 1 in accordance with some embodiments of the present disclosure.

FIG. 3 depicts a flow diagram illustrating a method for improving gas flow in accordance with some embodiments of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of methods and apparatus for improving gas flow are provided herein. Embodiments of the apparatus may advantageously decrease non-uniformities in the deposition of materials on a substrate. Embodiments of the inventive apparatus may advantageously be easily retrofitted to existing processing systems, thereby avoiding unnecessary and costly modification of existing processing systems. Although useful for many processes, the apparatus disclosed below is illustratively described with respect to the deposition of titanium nitride (TiN) via atomic layer deposition (ALD).

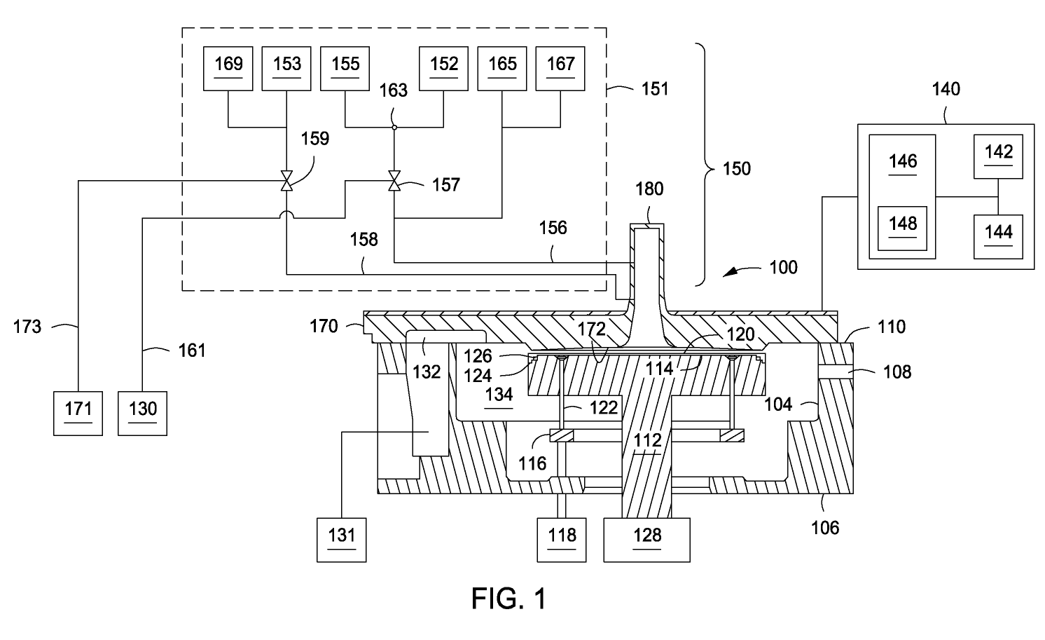

FIG. 1 is a schematic cross-sectional view of an illustrative substrate processing chamber 100 in accordance with embodiments of the present disclosure. Other substrate processing chambers may benefit from modification in accordance with the teachings provided herein, for example, the GEMINI ALD chamber and the ALD2 TaN chamber, available from Applied Materials, Inc., of Santa Clara, Calif.

The substrate processing chamber 100 includes a chamber body 106 and a chamber lid 170 disposed on an upper surface 110 of the chamber body 106 to define an inner volume 134. A substrate support 112 supports the substrate 120 on a substrate supporting surface 114. The substrate support (or pedestal) 112 is mounted to a lift motor 128 to raise or lower the substrate support 112 and a substrate 120 disposed thereon. A lift plate 116 coupled to a lift motor 118 is mounted in the substrate process chamber 100 and raises or lowers pins 122 movably disposed through the substrate support 112. The pins 122 raise or lower the substrate 120 over the surface of the substrate support 112. In some embodiments, the substrate support 112 includes a vacuum chuck, an electrostatic chuck, or a clamp ring for securing the substrate 120 to the substrate support 112. An opening 108 formed in a wall 104 of the chamber body 106 facilitates entry and egress of a substrate into and out of the substrate processing chamber 100.

The substrate support 112 is heated to increase the temperature of the substrate 120 disposed thereon. For example, the substrate support 112 may be heated using an embedded heating element, such as a resistive heater or may be heated using radiant heat, such as heating lamps disposed above the substrate support 112. A purge ring 124 is disposed on the substrate support 112 to define a purge channel 126 which provides a purge gas to a peripheral portion of the substrate 120 to prevent deposition thereon.

An exhaust system 131 is in communication with a pumping channel 132 to evacuate any undesirable gases from the substrate process chamber 100. The exhaust system 131 also helps in maintaining a desired pressure or a desired pressure range inside the substrate process chamber 100.

The gas delivery system 150 is coupled to a gas passageway 180 formed in or coupled to the chamber lid 170 to selectively provide precursor gases, reactant gases, carrier gases, purge gases, or combinations of these gases, to the substrate process chamber 100. The gas delivery system 150 comprises a gas panel 151 having a plurality of gas sources 152, 155, 165, 167 and a plurality of valves (two shown) 157, 159 coupled to one or more conduits (e.g., conduits 156, 158) to control a flow of gas from the gas panel 151 to the substrate process chamber 100. In some embodiments, the gas panel 151 is configured to combine at least some of the gases provided prior to reaching the valve 157. For example, in some embodiments, the valve 157 may be disposed downstream of a junction 163 coupling gas sources 152, 155 to selectively provide the gases to the substrate processing chamber 100 via the conduit 156 or divert the gases to the exhaust system 130 via a conduit 161. In some embodiments, the valves 157, 159 are switching valves, high speed valves, stop valves, or the like, to facilitate pulsing the gas provided by the gas panel 151. In some embodiments the valves 157, 159 are two way valves, for example, diverter valves configured to divert the flow of the process gas from the gas panel away from the substrate process chamber 100 via, for example, conduits 161, 173. In some embodiments, the conduits 161, 173 are coupled to exhaust systems 130, 171. The exhaust systems 130, 171 may be the same exhaust system or they may be different exhaust systems. Additional gas sources 153 and 169 are coupled to the gas passageway 180 via conduit 158 to provide additional gases to the gas passageway 180. For example, in some embodiments, either or both of the gas sources 153 and 169 may be a precursor gas source to provide a constant flow of a precursor gas for example, such as, titanium tetrachloride (TiCl₄) or ammonia (NH₃).

In some embodiments, for example, such as where a solid or liquid precursor is utilized, the gas delivery system 150 may also comprise one or more ampoules. In such embodiments, the one or more ampoules may be configured to allow the solid or liquid precursor to be contained and sublime into gaseous form for delivery into the substrate process chamber 100.

A controller 140, such as a programmed personal computer, work station computer, or the like is coupled to the substrate process chamber 100. Illustratively, the controller 140 comprises a central processing unit (CPU) 142, support circuitry 144, and a memory 146 containing associated control software 148. The controller 140 controls the operating conditions of processes performed in the process chamber, for example, an ALD process, such as the method 300 described below. For example, the controller 140 may be configured to control the flow of various precursor gases and purge gases from the gas delivery system 150 to the substrate process chamber 100 during different stages of the deposition cycle.

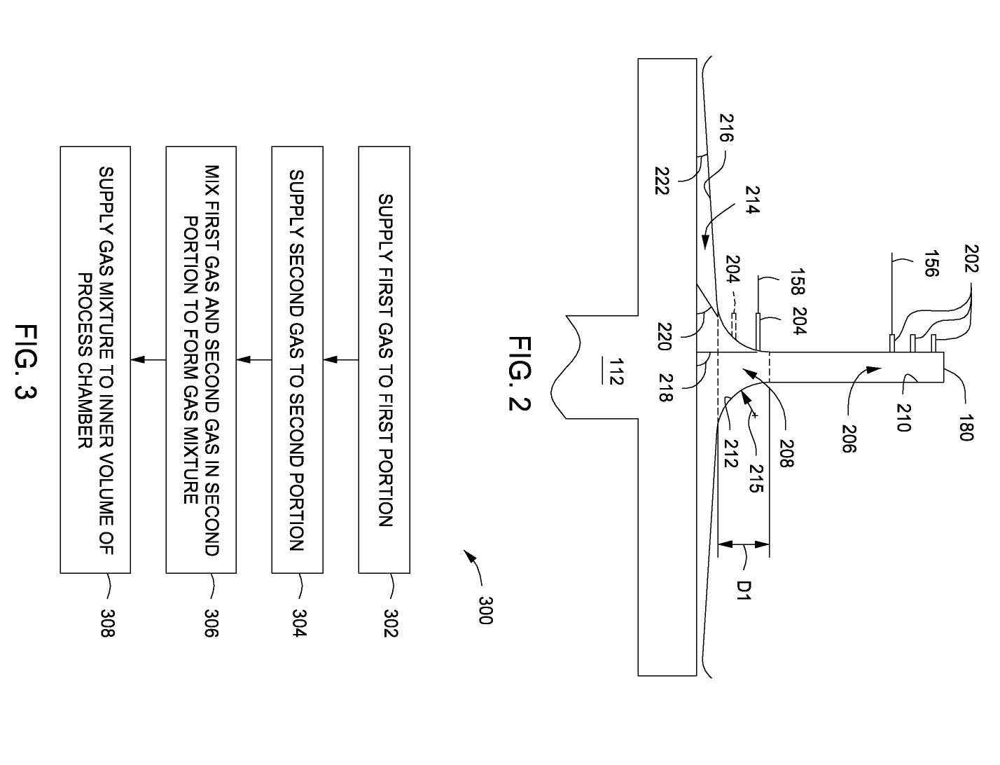

A bottom surface 172 of the chamber lid 170 is tapered to form an expanding channel (e.g., gas passageway 180) to a peripheral portion of the chamber lid 170. For example, FIG. 2 depicts a view of the gas passageway 180 of FIG. 1 in accordance with some embodiments of the present disclosure. The gas passageway 180 includes a first portion 206 having an inner sidewall 210, a second portion 208 having an inner sidewall 212, and a third portion 214 having an inner sidewall 216. The inner sidewall 210 of the first portion 206 is disposed at a first angle 218 with respect to the support surface of the substrate support 112. The inner sidewall 212 of the second portion is disposed at a second angle 220 with respect to the support surface of the substrate support 112. The second angle is less than the first angle. The inner sidewall 216 of the third portion is disposed at a third angle 222 with respect to the support surface of the substrate support 112. The third angle is less than the second angle.

Generally, the first angle 218 may be about 70 to about 110 degrees, or about 90 degrees. The third angle 222 may be about may be about 2 to about 12 degrees, or about 5 degrees. The second angle 220 varies along the inner sidewall 212 or the second portion and may be any value between the first and third angles 218, 222, inclusively.

In some embodiments, the first portion 206 is straight (i.e., the first angle 218 is substantially 90 degrees) and the second and third portions 208, 214 are divergent. However, in some embodiments, the entire gas passageway 180 may be divergent (e.g., funnel-shaped). A straight first portion 206 advantageously results in improved deposition uniformity at a center of the substrate 120.

A diameter of the first portion 206 may be about 0.5 to about 0.9 inches (e.g., about 0.63 inches). The second portion 208 ranges in diameter as it increases from adjacent the first portion 206 to adjacent the third portion 214. A diameter of the second portion 208 may be about 0.5 to about 6 inches. In some embodiments, the second portion 208 may be defined by a radius 215 blending or connecting the first portion 206 to the third portion 214. In some embodiments, the radius 215 may be about 0.7 to about 1.5 inches (e.g., about 1 inch). These values are exemplary and pertain to substrates with a 12 inch diameter. For larger or smaller substrates, the diameters of the first portion 206, the second portion 208, and the radius would need to be increased or decreased accordingly.

To improve gas flow, a transition from the first portion 206 to the second portion 208 is gradual (i.e., smooth). In addition, the transition from the second portion 208 to the third portion 214 is gradual (i.e., smooth). The expanding gas passageway 180 improves a velocity profile of gas flow from the gas passageway 180 across the surface of the substrate 120 (i.e., from the center of the substrate to the edge of the substrate).

One or more first gas inlets 202 (three first gas inlets 202 shown in FIG. 2) are coupled to the first portion 206 and one or more second gas inlets 204 (two second gas inlets 204 shown in FIG. 2) are coupled to the second portion 208. The second gas inlet 204 may be coupled to the second portion 208 at any point along a length D1 of the second portion 208. For example, in some embodiments, a second gas inlet 204 may be coupled to a section of the second portion 208 with a diameter of 1.6 inches and an optional second gas inlet 204 may be coupled to a section of the second portion 208 with a diameter of 6 inches. In some embodiments, the second gas inlet 204 may be coupled to a lower area of the first portion 206.

The first gas inlet 202 is coupled to the conduit 156, for example, to supply one or more reactant and/or precursor gases to the gas passageway 180 at a first flow rate. The second gas inlet 204 is coupled to the conduit 158, for example, to supply additional precursor gas to the gas passageway 180 at a second flow rate. The addition of the precursor gas at the second portion 208 advantageously increases the supply of precursor in the second portion 208 of the gas passageway 180. As a result, a more uniform deposition of material is realized across the substrate 120 (i.e., the deposition profile along the edge and center portions of the substrate are more uniform).

FIG. 3 depicts a flowchart of a method 300 for processing a substrate in accordance with some embodiments of the present disclosure. The method generally begins at 302, where a first gas is supplied to the first portion 206 of the gas passageway 180 at a first flow rate via the first gas inlet 202. The first gas may include one or more reactant and/or precursor gases. At 304, a second gas is supplied to the second portion 208 of the gas passageway 180 at a second flow rate via the second gas inlet 204. Next, at 306, the first and second gases are mixed in the second portion 208. The divergent shape of the second portion 208 facilitates the mixing of the gases together. At 308, the gas mixture is supplied to the inner volume 134 for deposition onto the substrate 120. A ratio of the second flow rate to the first flow rate is predetermined depending on the specific process being performed in the substrate process chamber 100. For example, when depositing titanium nitride (TiN), the inventors have discovered that a flow rate ratio of about 1:7 to about 1:9.5 when titanium tetrachloride (TiCl₄) is used and about 1:2 to about 1:5 when ammonia (NH₃) is used as the precursor results in improved deposition uniformity.

While the foregoing is directed to embodiments of the present disclosure, other and further embodiments of the disclosure may be devised without departing from the basic scope thereof.

1. A substrate processing chamber, comprising:
a chamber body and a chamber lid defining an interior volume;
a substrate support disposed within the interior volume and having a support surface to support a substrate;
a gas passageway disposed in the lid opposite the substrate support to supply a gas mixture to the interior volume, the gas passageway including a first portion and a second portion, wherein the first portion has an inner sidewall disposed at a first angle with respect to the support surface of the substrate support, and wherein the second portion has an inner sidewall disposed at a second angle with respect to the support surface, wherein the second angle is less than the first angle;
a first gas inlet disposed in the first portion to supply a first gas to the first portion of the gas passageway; and
a second gas inlet disposed in the second portion to supply a second gas to the second portion.

2. The substrate processing chamber of claim 1, wherein the first portion is straight.

3. The substrate processing chamber of claim 1, wherein the first gas inlet includes a plurality of gas inlets.

4. The substrate processing chamber of claim 1, wherein the second gas inlet is a single gas inlet.

5. The substrate processing chamber of claim 1, wherein the second gas inlet is coupled to a precursor gas source.

6. The substrate processing chamber of claim 1, wherein a transition from the first portion to the second portion is gradual.

7. The substrate processing chamber of claim 1, wherein the second gas inlet is disposed at any point along a length of the second portion.

8. The substrate processing chamber of claim 1, wherein a diameter of the first portion is about 0.5 to about 0.9 inches.

9. The substrate processing chamber of claim 1, wherein the second portion is defined by a radius of about 0.25 to about 3 inches.

10. The substrate processing chamber of claim 1, wherein the gas passageway further comprises a third portion disposed adjacent the second portion opposite the first portion, wherein the third portion has an inner sidewall disposed at a third angle with respect to the support surface, wherein the third angle is less than the second angle.

11. The substrate processing chamber of claim 10, wherein the third angle is about 2 to about 12 degrees.

12. A substrate processing chamber, comprising:
an interior volume;
a substrate support disposed within the interior volume;
a gas passageway disposed above the substrate support to supply a gas mixture to the interior volume, the gas passageway including a straight portion and a divergent portion;
a plurality of first gas inlets to supply at least one gas to the straight portion at a first flow rate; and
a second gas inlet to supply a second gas to the divergent portion at a second flow rate.

13. The substrate processing chamber of claim 12, wherein a transition from the straight portion to the divergent portion is gradual.

14. The substrate processing chamber of claim 12, wherein the second gas inlet is disposed at any point along a length of the divergent portion.

15. The substrate processing chamber of claim 12, wherein a diameter of the straight portion is about 0.5 to about 0.9 inches.

16. The substrate processing chamber of claim 12, wherein the divergent portion includes a second portion defined by a radius of about 0.25 to about 3 inches.

17. A method of processing a substrate in a process chamber, comprising:
supplying a first gas to a first portion of a gas passageway disposed above a substrate support via a first gas inlet at a first flow rate;
supplying a second gas to a second portion of the gas passageway via a second gas inlet at a second flow rate, wherein the second portion of the gas passageway is closer to the substrate support than the first portion;
mixing the first and second gases in the second portion to create a gas mixture; and
supplying the gas mixture to an inner volume of the process chamber.

18. The method of claim 17, wherein the first gas comprises a gas mixture including a precursor gas, and wherein the second gas comprises the precursor gas.

19. The method of claim 18, wherein the precursor gas is one or more of titanium tetrachloride (TiCl₄) or ammonia (NH₃).

20. The method of claim 19, wherein the precursor gas is titanium tetrachloride (TiCl₄) and a flow rate ratio of the second flow rate to the first flow rate is about 1:9, or wherein the precursor gas is ammonia (NH₃) and the flow rate ratio of the second flow rate to the first flow rate is about 1:3.
